(19) United States
(12) Patent Application Publication
(10) Pub. No.: US 2006/0214251 A1
(43) Pub. Date: Sep. 28, 2006

(54) Photodiodes with anti-reflection coating

(75) Inventors: Perumal Ratnam, Freemont, CA (US); Dong Zheng, San Jose, CA (US)

Correspondence Address: AKERMAN SENTERFITT, P.O. BOX 3188, WEST PALM BEACH, FL, 33402-3188, US

(73) Assignee: INTERSIL AMERICAS INC., Milpitas, CA (US)

(21) Appl. No.: 11/378,843

(22) Filed: Mar. 17, 2006

Related U.S. Application Data
(60) Provisional application No. 60/663,239, filed on Mar. 18, 2005.

(51) Int. Cl. H01L 31/0232; H01L 21/4763

(52) U.S. Cl. 257/437; 438/636; 257/E31.119

(57) ABSTRACT

A method of forming efficient photodiodes includes the steps of providing a substrate having a p-surface region on at least a portion thereof, implanting a shallow n-type surface layer into the surface region, and forming a multilayer first anti-reflective (AR) coating on the n-type surface layer. The surface layer is preferably an As or Sb surface layer. The forming the AR step include the steps of depositing or forming a thin oxide layer having a thickness of between 1.5 nm and 8 nm on the shallow surface layer, and depositing a second dielectric different from the thin oxide layer on the thin oxide layer, such as a silicon nitride layer.

### CROSS-REFERENCE TO RELATED APPLICATIONS

This application claims the benefit of Provisional Application No. 60/663,239 filed on Mar. 18, 2005, which is incorporated by reference in its entirety in the present application.

### FIELD OF THE INVENTION

The invention generally relates to photodiodes, and more particularly to semiconductor photodiodes that have at least one anti-reflective layer, and a process for its fabrication to form integrated circuit devices that include photodiodes.

### BACKGROUND OF THE INVENTION

The structure and function of semiconductor photodiodes are well known. Photodiodes convert photons into electrical energy. Conventional photodiodes operate in the visible and near-infrared range of the electromagnetic radiation spectrum. The particular semiconductor materials used determine the particular wavelength or wavelength range of the radiation to which the photodiode responds. Photodiodes can be fabricated from elemental semiconductors, such as silicon, as well as compound semiconductors, such as gallium-arsenide.

A conventional photodiode includes a surface P-type anode region to which an anode contact is formed. An antireflective film generally overlies the P-type region to assure a high degree of transmission of radiation at the wavelength that the photodiode is designed to absorb. Beneath the P-type region is a very lightly-doped N-type drift region in which photons of the incident radiation are absorbed, generating hole-electron pairs. Adjoining the N-type drift region is a heavily-doped N+ cathode region, to which a cathode contact is formed at a surface of the device. In operation the PN junction between the P-type anode region and the N-type drift region is reverse biased by an applied potential expanding the depletion layer on both sides of the junction. Because the N-type drift region is relatively lightly doped, the depletion layer is predominantly on the N-type side of the junction extending deeply into the drift region. Holes and elections generated in the depletion layer are swept in opposite directions in response to the applied potential, thus providing a current that is a function of the intensity of the incident radiation.

In many applications photodiodes are formed on integrated circuit die. As a result, when integrating photodiodes on the same semiconductor chip as other circuit elements such as transistors and resistors to perform complex functions in response in part to incident radiation signals, the constraints of the process for making such other elements must be considered in the design of the photodiode. It is desirable to minimize the complexity of a semiconductor fabrication process while maximizing the flexibility available to the designer to provide complex functionality in the device design. The inclusion of a photodiode on an integrated circuit chip made with state-of-the-art CMOS or BiCMOS process technology contributes to the foregoing design considerations.

### SUMMARY OF THE INVENTION

A method of forming efficient photodiodes comprises the steps of providing a substrate having a p-surface region on at least a portion thereof, implanting a shallow n-type surface layer into the surface region, and forming a multilayer first anti-reflective (AR) coating on the n-type surface layer. The surface layer is preferably an As or Sb surface layer. The forming the AR step comprises the steps of depositing or forming a thin oxide layer having a thickness of between 1.5 nm and 8 nm on the shallow surface layer, and depositing a second dielectric different from the thin oxide layer on the thin oxide layer.

The thickness of second dielectric is preferably about an odd integer multiplied by ¼ of an optical wavelength in the second dielectric to be processed. The second dielectric layer can comprises silicon nitride. The method can further comprise the step of forming a second AR coating on the first AR coating. In this embodiment, a passivation layer is generally disposed between the first and second AR coating. The passivation layer can comprises silicon nitride over silicon dioxide, wherein said silicon nitride component of said passivation layer is removed over the photodiode.

A photodiode comprises a substrate having a p-surface region on at least a portion thereof, an n-type surface layer into the surface region, and a multi-layer first anti-reflective (AR) coating on the n-type surface layer. The first AR coating comprises a thin oxide layer having a thickness of between 1.5 and 8 nm on said shallow surface layer, and a second dielectric layer different from the thin oxide layer on the thin oxide layer. A thickness of the second dielectric is about (±5%, preferably ±12%) of an odd integer multiplied by ¼ of an optical wavelength in the second dielectric to be processed. The n-type surface layer preferably comprises a shallow As or Sb layer. The second dielectric layer can comprise silicon nitride. The photodiode can further comprise a second AR coating on said first AR coating, and a passivation layer disposed between said first and second AR coating.

### BRIEF DESCRIPTION OF THE DRAWINGS

A fuller understanding of the present invention and the features and benefits thereof will be accomplished upon review of the following detailed description together with the accompanying drawings, in which:

FIG. 1 shows a cross section of the resulting intermediate photodiode structure after SAB/nitride etch.

FIG. 2 shows a cross section of the resulting intermediate photodiode structure following standard CMOS multi-level metal processing including metallization, CVD ILD deposition, and contact etch.

FIG. 3 shows a cross section of the resulting final photodiode structure. The passivation nitride has been removed from the photodiode window.

FIG. 4 is bandwidth data obtained from photodiodes according to the invention which evidence a photodiode bandwidth of at least about 400 MHz.

### DESCRIPTION OF THE PREFERRED EMBODIMENTS

A method of forming efficient photodiodes comprises the steps of providing a substrate having a p-surface region on at least a portion thereof, implanting a shallow n-type surface layer into the surface region, and forming a multilayer first anti-reflective (AR) coating on the n-type surface layer. The surface layer is preferably an As or Sb surface layer.

The shallow n-type surface layer has bound found to provide high conversion efficiency. The first AR coating provides has been found to provide good uniformity of conversion efficiency and control from lot to lot, diode to diode and also across the diode. With the first AR coating as described herein, ≦+/−2% variation in efficiency have been obtained across the photodiode as compared to around 10% without the first AR coating.

The forming the AR step comprises the steps of depositing or forming a thin oxide layer having a thickness of between 1.5 nm and 8 nm on the shallow surface layer, and depositing a second dielectric different from the thin oxide on the thin oxide layer. The second dielectric generally has a refractive index significantly greater than the refractive index of silicon dioxide. Although the second dielectric is generally described herein as being silicon nitride, the invention is not limited to silicon nitride as the second dielectric. For example, the second dielectric can be silicon rich SiO₂, silicon rich SiON or silicon rich Si₃N₄. One known method for depositing such silicon rich layers is using plasma enhanced deposition systems.

A thickness of the second dielectric layer is preferably equal to an odd integer multiplied by ¼ of an optical wavelength in the second dielectric to be processed. In a preferred embodiment, the refractive index of the second dielectric layer is found by taking the square root of the product of the refractive index of the n-type Si surface layer and the silicon dioxide layer interlayer dielectric (ILD) generally disposed on the dense dielectric layer (3.75*1.46)^{1/2}=2.33 (optimized for blue light; 405 nm).

The thicknesses of thin oxide layer and second dielectric layer are selected depending on the wavelength of the light to which the photodiode is designed to respond in its end-use application. The thicknesses are selected to achieve at least 99% transmission of the incoming light through the second dielectric and oxide layers down into the underlying silicon using the formula given above. By way of example, for a 405 nm (blue) optical wavelength, the first AR coating preferably comprises a 130 to 150 nm thick silicon nitride layer on top of a silicon dioxide layer having a thickness of less than 6 nm. It has been found that the reflection for 405 nm light for such a structure when an As surface layer is provided can be reduced to less than 1% (>99% transmission).

Anti-reflection coatings (ARC) are known to increase photodetector responsivity. ARC coatings according to the invention strongly reduce undesired effects from optical interference thus largely eliminating optical interference. As noted above, reflections can be reduced to less than 1%, thus increasing photodiode efficiency.

The P-substrate is preferably a silicon substrate having a resistivity of about 10 to 20 ohm-cm. Alternatively, the p-surface region can be a p-well diffused into an n-substrate.

The phrase “shallow n-type surface layer”, as used herein, refers to a 200 nm or less deep junction depth. In a preferred embodiment, the surface layer is As formed using an As implant dosage of 1×10¹⁴ to 5×10¹⁴/cm² at about 10 to 25 Kev. Alternatively, other heavy/slow diffusing n-type Si dopants, including antimony (Sb) or even bismuth (Bi), can be used.

In a preferred embodiment of the invention a second AR coating is formed on the first AR coating. A passivation layer is disposed between the first and second AR coatings. The passivation layer is preferably an oxynitride layer. In one embodiment, the second AR coating preferably has a refractive index of about 1.22 to generally match the passivation dielectric/air interface in the case of an oxide passivation. However, if the passivation is oxynitride, where the refractive index of the oxynitride can vary from 1.46 to 2.15, the refractive index of the second AR coating should be adjusted to account for the refractive index of the passivation. In one embodiment, the second AR coating comprises MgF₂ in combination with TiO₂/SiO₂. The thickness of the second AR coating is preferably set by an odd integer multiplied by ¼ of an optical wavelength in the second AR coating.

The process flow including AR coatings according to the invention is compatible with most standard CMOS OR BiMOS processes. Only minor process changes to standard processes are generally needed to implement both the first and optional second AR coatings. The first AR process can be implemented with or without any additional masks. The second AR will generally require one additional mask.

Although various conventional semiconductor device fabrication techniques can be used to make photodiodes according to the invention, an exemplary process sequence is described below. The exemplary process described below starts with the step of the shallow As photodiode (PD) implant, which is preferably after the source/drain implant in the process sequence. The source/drain implant provides low resistance contacts on both sides of the n-type surface layer of the photodiode to be formed. Prior to the PD implant, the thin oxide layer, which provides the bottom portion of the first AR is deposited or grown to a thickness of 2 to 6 nm. A new masking level is preferably used to allow selective PD implantation in the photodiode region. However, although not preferred, the oxide layer can be grown after the PD implant. A thermal activation step generally follows, such as a rapid thermal anneal (RTA). The nitride top portion of the first AR coating is then deposited. A source/drain anneal generally follows this step.

The thin silicon dioxide layer (1.5 to 8 nm) disposed between the nitride layer (or other second dielectric) and the Si surface of the photodiode is used to reduce tension/stress between the Si and the silicon nitride or other second dielectric. For optical performance, a 1.5 nm to 4 nm thick, such as a 2 nm or 3 nm thick, thin silicon dioxide layer is preferred. Due to the silicon dioxide layer beginning to affect the reflected phase wave for thin oxide thicknesses generally being 4 nm to 5 nm or greater, the nitride thickness is preferably thinned slightly to account for the thin silicon dioxide layer, and restore the optical performance of the device to an optimum or near optimum value. For example, if the silicon dioxide layer is 5 nm thick, the optimum nitride thickness is reduced from 145 nm to about 140 nm for 405 nm operation. The thickness tolerance of the second dielectric layer should be within +/−10 nm of the calculated optimum value as described below, and is preferably within +/−5 nm.

In the case of the second dielectric being silicon nitride, the nitride thickness is preferably found using the following relation:
Thickness=n*(¼ of the optical wavelength in nitride), where n=1, 3 or 5, . . . For 405 nm operation, using n=1, the preferred nitride thickness is:
(¼* 405 nm)/2.1=48 nm, while n=3 results in a thickness of 144 nm.

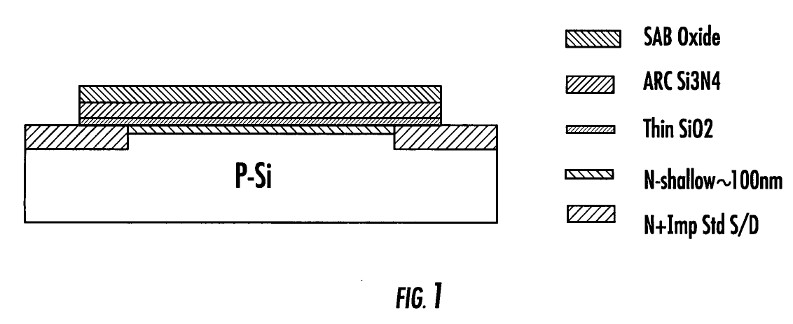

In the exemplary process described herein, the next step is a salicide block (SAB) oxide deposition. The SAB mask and etch process can be modified so that the AR nitride can be etched during the SAB etch to define the active photodiode region. This step saves a thin nitride mask level. A cross section of the resulting structure after the SAB/nitride etch is shown in FIG. 1.

In one process variant, the N+ plug implants the contacts of the photodiode. Accordingly, the SAB layer can overlap the contact in this flow. Moreover, the shallow n-type implant can be extended into the contact area (along with the plug implant), and the SAB layer can cover the photodiode contacts. In an alternate embodiment the SAB layer can overlap the contact, since there is no need for silicide over the contact area, provided there is a plug implant.

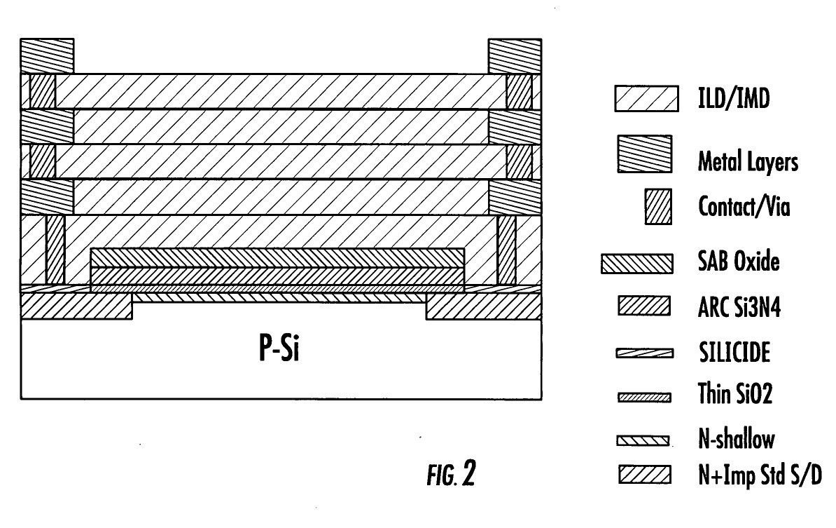

Following standard CMOS CVD ILD deposition and contact etch alternated with conventional metal processing provides a multi-level metal interconnect and results in the structure shown in FIG. 2. A passivation layer is then deposited, such as an oxynitride (SiN/oxide) layer capped with a nitride layer.

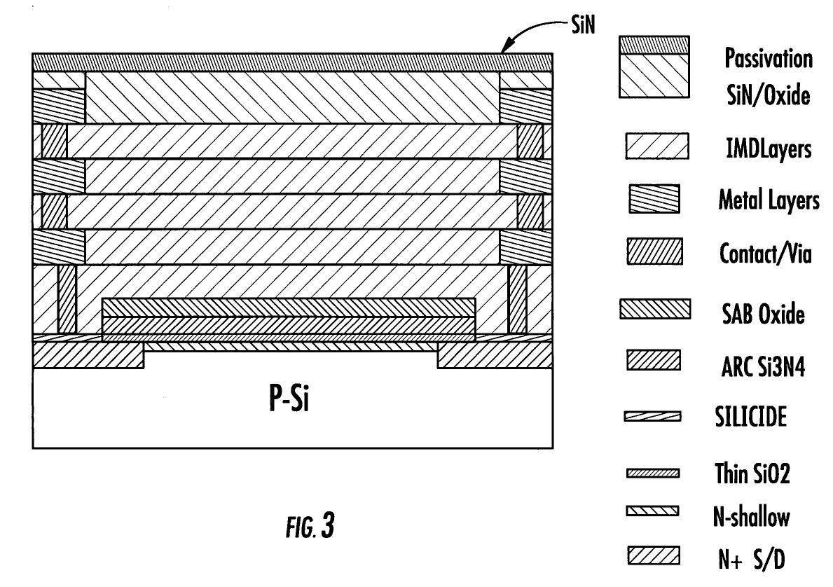

An added masking level is then preferably used to etch open the photodiode window. The second AR coating is then optionally deposited on the die thus covering the photodiode area resulting in the final structure photodiode structure shown in FIG. 3.

In an alternative process sequence, the multilayer first AR coating is formed after passivation processing. Specifically, following passivation deposition, a masking level can be used to remove the passivation and ILD layers to expose the photodiode surface. The first AR coating according to the invention can then be formed. In this case, a second AR coating is not needed.

A plurality of PMOS and NMOS transistors and photodiodes according to the invention can be elements of an integrated circuit that is useful in various different applications in which light signals are used as inputs to electronic circuitry within a larger apparatus or system. For example, certain optoelectronic systems use blue light at a wavelength of 405 nanometers. Photodiodes can be structured to respond to such blue light, or other desired wavelengths.

For example, photodiodes according to the invention for the UV/blue spectral rangeintegrated monolithically with CMOS circuits with a high sensitivity in the UV/blue spectral range are needed for optical storage systems, such as digital versatile disk (DVD) or digital video recorders (DVR). Although described using the preferred n− surface layer diffused into a p− region, a p− surface layer can also be diffused into an n−region provide a p− surface layer can be sufficiently shallow.

### EXAMPLES

It should be understood that the Examples described below are provided for illustrative purposes only and do not in any way define the scope of the invention.

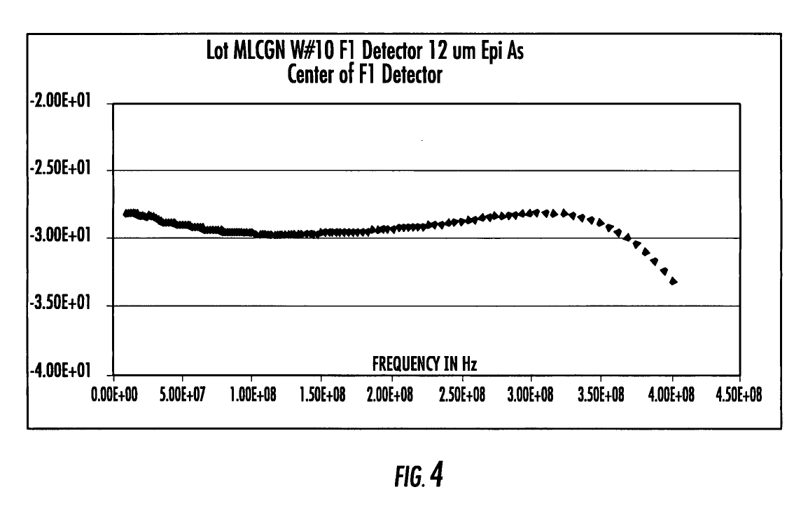

An experiment was performed to asses photodiode efficiency and bandwidth obtained using the exemplary process sequence described above. The photodiodes were 660μ by 660μ. A blue laser operating at 4.5 mW of power was used as the light source. The resulting photogenerated current was measured @ 1.5 V across the photodiode junction. The resulting efficiency in A/W ranged from 0.215 to 0.232. Bandwidth data was also taken. FIG. 4 shows photodiode bandwidth of at least about 400 MHz.

It is to be understood that while the invention has been described in conjunction with the preferred specific embodiments thereof, that the foregoing description as well as the examples which follow are intended to illustrate and not limit the scope of the invention. Other aspects, advantages and modifications within the scope of the invention will be apparent to those skilled in the art to which the invention pertains.

1. A method of forming efficient photodiodes, comprising the steps of:
providing a substrate having a p− surface region on at least a portion thereof;
implanting a n-type surface layer into said surface region, and
forming a multi-layer first anti-reflective (AR) coating on said n-type surface layer, wherein said forming step comprises the steps of:
depositing or forming a thin oxide layer having a thickness of between 1.5 nm and 8 nm on said n-type surface layer;
depositing a second dielectric layer different from said thin oxide layer on said thin oxide layer.

2. The method of claim 1, wherein a thickness of said second dielectric is about an odd integer multiplied by 1 of an optical wavelength in said second dielectric to be processed.

3. The method of claim 1, wherein said second dielectric layer comprises silicon nitride.

4. The method of claim 1, wherein said n-type surface layer comprises a shallow As or Sb layer.

5. The method of claim 1, further comprising the step of forming a second AR coating on said first AR coating.

6. The method of claim 5, further comprising the steps of forming a passivation layer disposed between said first and second AR coating.

7. The method of claim 6, wherein said passivation layer comprises silicon nitride over silicon dioxide, wherein said silicon nitride component of said passivation layer is removed over said photodiode.

8. A photodiode, comprising:
a substrate having a p-surface region on at least a portion thereof;
an n-type surface layer diffused into said surface region, and
a multi-layer first anti-reflective (AR) coating on said n-type surface layer, wherein said first AR coating comprises:
a thin oxide layer having a thickness of between 1.5 and 8 nm on said n-type surface layer;
a second dielectric layer different from said thin oxide layer on said thin oxide layer.

9. The photodiode of claim 8, wherein a thickness of said second dielectric is about an odd integer multiplied by ¼ of an optical wavelength in said second dielectric to be processed.

10. The photodiode of claim 8, wherein said n-type surface layer comprises a shallow As or Sb layer.

11. The photodiode of claim 8, wherein said second dielectric layer comprises silicon nitride.

12. The photodiode of claim 8, further comprising a second AR coating on said first AR coating, and a passivation layer disposed between said first and second AR coating.
